(19) United States
(12) Patent Application Publication
(10) Pub. No.: US 2022/0231122 A1
(43) Pub. Date: Jul. 21, 2022

(54) SEMICONDUCTOR STRUCTURE AND MANUFACTURING METHOD THEREOF

(71) Applicant: CHANGXIN MEMORY TECHNOLOGIES, INC., Hefei City (CN)

(72) Inventor: Chih-Cheng LIU, Hefei City (CN)

(21) Appl. No.: 17/451,334

(22) Filed: Oct. 19, 2021

Related U.S. Application Data
(63) Continuation of application No. PCT/CN2021/112943, filed on Aug. 17, 2021.

(30) Foreign Application Priority Data
Jan. 20, 2021 (CN) 202110075188.6

(51) Int. Cl. H01L 29/06; H01L 21/762; H01L 21/02

(52) U.S. Cl. CPC H01L 29/0649; H01L 21/02282; H01L 21/762

(57) ABSTRACT

Provided are a semiconductor structure and a manufacturing method thereof. The semiconductor structure comprises a substrate having a trench therein, the trench including a corner between a bottom and a sidewall, the corner protruding in a direction away from an opening of the trench; a first isolation layer, covering a surface of the sidewall, a surface of the corner and a surface of the bottom; a second isolation layer, covering a surface of the first isolation layer, a hardness of a material of the second isolation layer being greater than that of the first isolation layer; and a stress adjustment layer, located in the first isolation layer between the corner and the second isolation layer, a hardness of the stress adjustment layer being greater than that of the first isolation layer.

### CROSS-REFERENCE TO RELATED APPLICATIONS

This application is a continuation application of International Patent Application No. PCT/CN2021/112943, filed on Aug. 17, 2021, which claims priority to Chinese Patent Application No. 202110075188.6, filed with the Chinese Patent Office on Jan. 20, 2021 and entitled “SEMICONDUCTOR STRUCTURE AND MANUFACTURING METHOD THEREOF”. International Patent Application No. PCT/CN2021/112943 and Chinese Patent Application No. 202110075188.6 are incorporated herein by reference in their entireties.

### TECHNICAL FIELD

The present disclosure relates to the field of semiconductors, and in particular to a semiconductor structure and a manufacturing method thereof.

### BACKGROUND

During preparation of a trench isolation structure, it is difficult to control a depth, width and morphology of a trench, and especially the control over the trench morphology determines the isolation capability of the trench isolation structure to a great extent.

For a trench formed by an existing preparation method, its corner may protrude in a direction away from an opening of the trench relative to a bottom, which easily causes stress concentration in a wafer; in this case, it is not conducive to the release of stress generated in the subsequent process. In severe cases, the wafer may be damaged or even scrapped.

### SUMMARY

An embodiment of the present disclosure provides a semiconductor structure, including: a substrate having a trench therein, the trench including a corner between a bottom and a sidewall, the corner protruding in a direction away from an opening of the trench; a first isolation layer, covering a surface of the sidewall, a surface of the corner and a surface of the bottom; a second isolation layer, covering a surface of the first isolation layer, a hardness of a material of the second isolation layer being greater than that of the first isolation layer; and a stress adjustment layer, located in the first isolation layer between the corner and the second isolation layer, a hardness of a material of the stress adjustment layer being greater than that of the first isolation layer.

An embodiment of the present disclosure further provides a manufacturing method of a semiconductor structure, including: providing a substrate having a trench therein, the trench including a corner between a bottom and a sidewall, the corner protruding in a direction away from an opening of the trench; forming a first isolation layer and a stress adjustment layer, the first isolation layer covering a surface of the sidewall, a surface of the corner and a surface of the bottom, the stress adjustment layer being located in the first isolation layer covering the surface of the corner, a hardness of a material of the stress adjustment layer being greater than that of the first isolation layer; and forming a second isolation layer, the second isolation layer covering a surface of the first isolation layer, a hardness of a material of the second isolation layer being greater than that of the first isolation layer.

### BRIEF DESCRIPTION OF DRAWINGS

One or more embodiments are illustrated in an exemplary manner by pictures in the corresponding drawings, and unless otherwise stated, the pictures in the drawings do not constitute a scale limitation.

FIG. 1 is a schematic cross-sectional structural diagram of a semiconductor structure; and

FIG. 2 to FIG. 7 are schematic cross-sectional structural diagrams corresponding to various steps of a manufacturing method of a semiconductor structure according to an embodiment of the present disclosure.

### DETAILED DESCRIPTION

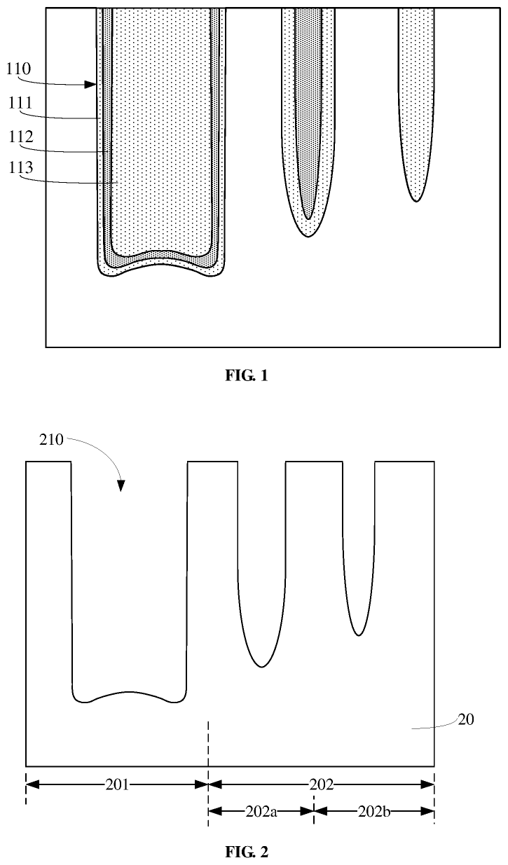

Referring to FIG. 1, an isolation structure filled in a trench 110 is composed of a first isolation layer 111, a second isolation layer 112, and a third isolation layer 113 stacked in sequence. A hardness of the second isolation layer 112 is greater than those of the first isolation layer 111 and the third isolation layer 113. The first isolation layer 111 is configured to protect a substrate and prevent the second isolation layer 112 with a higher hardness from coming into direct contact with the substrate, thereby preventing internal structures or devices of the substrate from being damaged by the second isolation layer 112, and ensuring that the internal structures or devices of the substrate have good electrical properties. The second isolation layer 112 is configured to suppress expansion of the third isolation layer 113, which is beneficial to preventing the expansion of the third isolation layer 113 from applying an excessive stress to the substrate, thereby alleviating the problem of stress concentration at the corner of the trench 110.

However, with the miniaturization of semiconductor structures, the problem of corner protrusions caused by an etching load effect is becoming more and more serious, that is, protrusions at the corners of the trench 110 relative to the bottom of the trench 110 are more and more serious, which then leads to a more prominent stress concentration problem at the corners of the trench 110. In addition, the stress concentration problem at the corner of the trench 110 has a greater impact on a miniaturized semiconductor structure than a semiconductor structure with a larger size, and the electrical properties of the miniaturized semiconductor structures are more susceptible to the stress concentration problem.

In order to solve the above problem, the embodiments of the present disclosure provide a semiconductor structure and a manufacturing method thereof. A stress adjustment layer with a relatively high hardness is arranged in a first isolation layer covering corners of a trench to reduce a stress on the corner of the trench and avoid the stress concentration problem at the corner of the trench, thereby improving wafer yield.

In order to make the objectives, technical solutions, and advantages of the embodiments of the present disclosure more clear, various embodiments of the present disclosures will be detailed below in combination with the accompanying drawings. However, a person of ordinary skill in the art can understand that in each embodiment of the present disclosure, many technical details are provided for readers to better understand the present disclosure. However, even if these technical details are not provided and based on variations and modifications of the following embodiments, the technical solutions sought for protection in the present disclosure can also be implemented.

FIG. 2 to FIG. 7 are schematic cross-sectional structural diagrams corresponding to various steps of a manufacturing method of a semiconductor structure according to an embodiment of the present disclosure.

Referring to FIG. 2, a substrate 20 is provided. The substrate 20 has a trench 210 therein, and the trench 210 includes a corner between a bottom and a sidewall.

A semiconductor device can generally be divided into a peripheral region 201 and an array region 202. The array region 202 can further be divided into a sparse region (ISO) 202a close to the peripheral region 201 and a dense region (DENSE) 202b far away from the peripheral region 201. A device density of the sparse region 202a is less than that of the dense region 202b. Limited by the device density, generally speaking, an opening width of the trench 210 configured to fill the isolation structure is designed according the following rule: the opening width of the trench 210 in the peripheral region 201>the opening width of the trench 210 in the sparse region 202a>the opening width of the trench 210 in the dense region 202b. Due to the etching load effect, the greater the opening width of the trench 210, the deeper the depth of the trench 210. Therefore, the depth of the trench 210 meets the following rule: the depth of the trench 210 in the peripheral region 201>the depth of the trench 210 in the sparse region 202a>the depth of the trench 210 in the dense region 202b.

Since the opening width of the trench 210 in the peripheral region 201 is relatively large, the etching load effect of the peripheral region 201 is more obvious. During the etching process, the corner of the trench 210 in the peripheral region 201 is more likely to protrude relative to the bottom. In other words, the corner of the trench 210 in the peripheral region 201 protrudes higher, this is more likely to cause the stress concentration problem, and the resulting stress concentration problem is usually more serious.

In some embodiments, only the isolation structure in the peripheral region 201 is improved, and the isolation structure in the array region 202 is not improved. In other embodiments, the isolation structure in the array region is also improved. It should be noted that according to the contour difference of the trenches in different regions, stress adjustment layers of different shapes and different materials may be arranged, and film layers of the isolation structure filled in the trenches may also be adjusted adaptively in terms of quantity and material.

In addition, since the isolation structure in the peripheral region 201 is not filled with a conducting medium while the isolation structure in the array region 202 may be filled with a conducting medium, such as a wordline, during improvements of the isolation structure in the array region 202, a material with a relatively low dielectric constant may be used as an additional material to replace an original material, thereby preventing a leakage current problem and an electric field concentration problem at the corner of the trench 210.

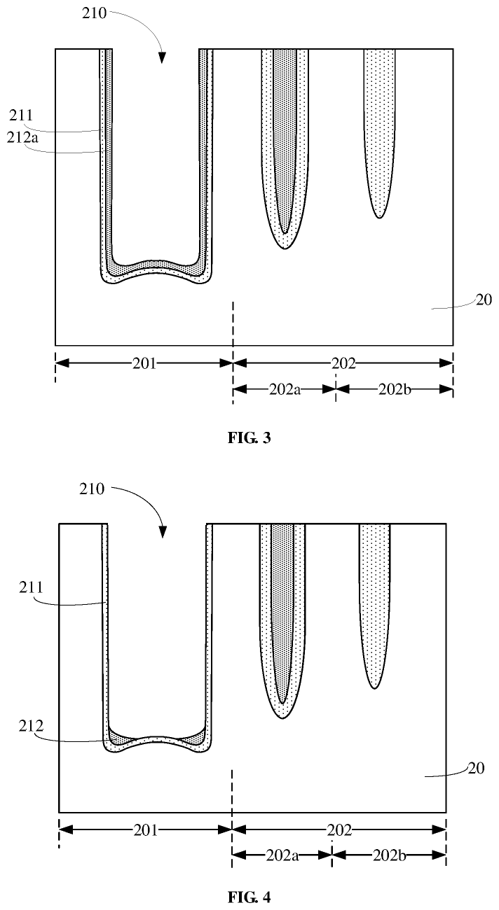

Referring to FIG. 3, a first isolation sublayer 211 and a stress adjustment film 212a are formed.

In some embodiments, the first isolation sublayer 211 covers the bottom surface, corner surface, and sidewall surface of the trench 210; since the opening width of the trench 210 in the dense region 202b is relatively small, the first isolation sublayer 211 can directly fill up the trench 210 in the dense region 202b; the stress adjustment film 212a covers the surface of the first isolation sublayer 211; since the opening width of the trench 210 in the sparse region 202a is relatively small, the stress adjustment film 212a can be further formed subsequently to fill up the trench 210 in the sparse region 202a on the basis of the first isolation sublayer 211.

In some embodiments, the hardness of the material of the stress adjustment film 212a is greater than the hardness of the material of the first isolation sublayer 211. Specifically, the material of the stress adjustment film 212a includes silicon nitride, and the material of the first isolation sublayer 211 includes silicon dioxide; accordingly, a thickness of the first isolation sublayer 211 is within a range of 2 nm to 10 nm, for example, 4 nm, 6 nm, or 8 nm.

In addition, since the corner protrudes in a direction away from the opening of the trench 210 relative to the bottom, the stress concentration problem at the corner of the film layer will be aggravated. Therefore, in order to avoid the above-mentioned problem in a film layer subsequently formed, the surface of the stress adjustment film 212a away from the corner should be set higher than or flush with the surface of the part of the first isolation sublayer 211 covering the bottom.

Referring to FIG. 4, a stress adjustment layer 212 is formed.

In some embodiments, after the formation of the stress adjustment film 212a (see FIG. 3), a part of the stress adjustment film 212a is etched by a plasma etching process, the stress adjustment film 212a on the surface of a part of the first isolation sublayer 211 is remained to serve as the stress adjustment layer 212, and the above-mentioned part of the first isolation sublayer 211 covers the corner surface of the trench 210. In other words, the stress adjustment layer 212 only covers the corner of the first isolation sublayer 211, while exposing the bottom and sidewall of the first isolation sublayer 211.

The first isolation sublayer 211 is located between the stress adjustment layer 212 and the substrate 20 to separate the stress adjustment layer 212 from the substrate 20. In this way, it is beneficial to preventing the electrical properties of other structures or devices in the substrate 20 from being damaged by the stress adjustment layer 212 with a relatively high hardness in contact with the substrate 20. In the meanwhile, it is also beneficial to suppressing expansion of the first isolation sublayer 211, preventing the expansion of the first isolation sublayer 211 from applying a great stress to the corners, alleviating the stress concentration problem at the corner, and preventing the expansion of the first isolation sublayer 211 from applying a great stress on the subsequently formed film layer and electrical components located in the film layer, thus ensuring that the subsequently formed film layer has better structural stability and that the electrical elements have good electrical properties.

In some embodiments, the stress adjustment layer 212 is located in the trench 210 in the peripheral region 201. Since a conducting medium is generally not formed in the trench 210 in the peripheral region 201, there is no need to consider the electric field problem and the leakage current problem at the corner. There is no requirement for the dielectric property of the stress adjustment layer 212. In this way, it is beneficial to expanding the optional range of the material of the stress adjustment layer, so that the material of the stress adjustment layer 212 can simultaneously meet the hardness requirement and other material requirements, such as thermal expansion rate, structural stability, cost, adhesion to surrounding film layers, and the like.

In still other embodiments, the trench in the peripheral region is filled with a conducting medium, or the stress adjustment layer is arranged in the trench in the array region, and the trench in the array region is filled with a conducting medium, such as a wordline; in the meanwhile, the corner may be damaged due to the stress concentration problem, and the damage may further cause the leakage current problem. In this case, a stress adjustment layer with a relatively low dielectric constant can be arranged; for example, the dielectric constant of the material of the stress adjustment layer is less than the dielectric constant of the material of the first isolation sublayer. In this way, it is beneficial to reducing the leakage current at the corner and alleviating the stress concentration problem at the corner.

Referring to FIG. 5, a second isolation sublayer 213 is formed.

In some embodiments, the second isolation sublayer 213 is formed after the formation of the stress adjustment layer 212; the second isolation sublayer 213 covers the sidewall and bottom of the first isolation sublayer 211 and the surface of the stress adjustment layer 212; the first isolation sublayer 211 and the second isolation sublayer 213 jointly constitute the first isolation layer, and the stress adjustment layer 212 is sealed in the first isolation layer. In other embodiments, the stress adjustment layer is formed after the formation of the first isolation layer; the first isolation layer may be formed step by step or at one time, and the first isolation layer exposes the stress adjustment layer.

In some embodiments, since the stress adjustment layer 212 exposes the bottom and sidewall of the first isolation sublayer 211, the second isolation sublayer 213 can cover the bottom and sidewall of the first isolation sublayer 211, that is, the second isolation sublayer 213 covers the surface of the first isolation sublayer 211 located at the bottom surface and sidewall surface of the trench 210. In the meanwhile, since a bonding force between two film layers made of a same material is greater than the bonding force between two film layers made of different materials, setting the material of the second isolation sublayer 213 to be the same as the material of the first isolation sublayer 211 is beneficial to improving the bonding force between the first isolation sublayer 211 and the second isolation sublayer 213, avoiding the problem of film layer displacement under stress, and improving the structural stability of the isolation structure.

Since a surface area of the stress adjustment layer is relatively small, an adhesion between the stress adjustment layer and the surrounding film layer is relatively small when the unit area adhesion is the same. Therefore, under the action of the stress, the stress adjustment layer 212 is more likely to be displaced relative to the first isolation sublayer 211 and the second isolation sublayer 213. In order to avoid the displacement of the stress adjustment layer, the adhesion between the stress adjustment layer 212 and the surrounding film layer can be improved, and a position limiting effect of the first isolation sublayer 211 and the second isolation sublayer 213 can be improved to ensure that the stress adjustment layer is in an original position under the action of an external force, so as to alleviate the stress concentration problem at the corner and avoid the damage to the isolation structure due to the displacement of the stress adjustment layer 212.

In some embodiments, the stress adjustment layer 212 may be made of a mixture of one or more materials, and may be formed by stacking one film layer or multiple film layers. For example, the stress adjustment layer 212 is composed of a middle part and a coat part wrapping the middle part, and the coat part is in contact with the first isolation sublayer 211 and the second isolation sublayer 213. In order to achieve various property requirements for the stress adjustment layer 212, including hardness requirement and adhesion requirement, the material properties of different film layers of the stress adjustment layer 212 can be adjusted; for example, a solution where the material of the middle part has a relatively high hardness and the material of the coat part has a relatively high adhesion to the first isolation sublayer 211 and the second isolation sublayer 213 can be adopted.

In some embodiments, the material of the first isolation sublayer 211 is the same as the material of the second isolation sublayer 213. This is also beneficial to reducing the difficulty in selecting the coat material and expanding available types of the coat material, so that lower-cost materials can be selected to make the coat part, and the cost of the stress adjustment layer 212 can be reduced.

In some embodiments, the thickness of the second isolation sublayer 213 is within a range of 2 nm to 10 nm, for example, 4 nm, 6 nm, or 8 nm. The thickness of the second isolation sublayer 213 may be equal to the thickness of the first isolation sublayer 211.

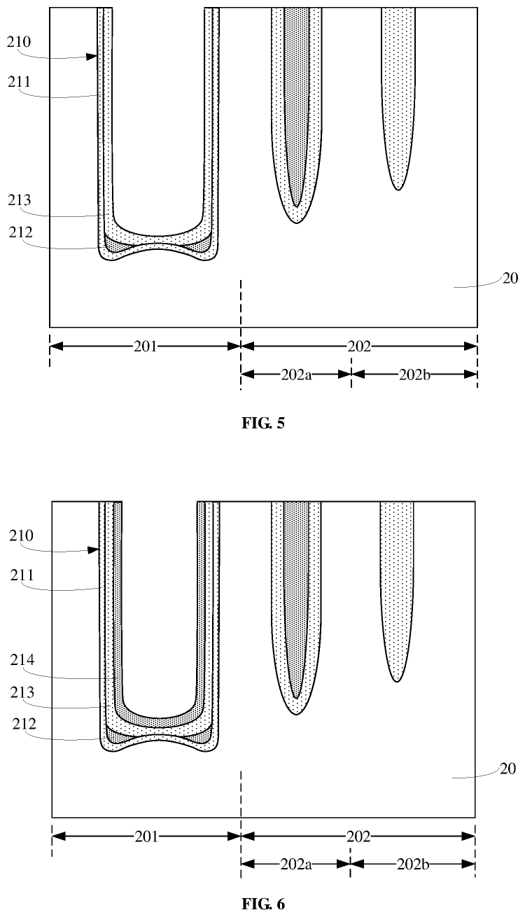

Referring to FIG. 6, a second isolation layer 214 is formed.

In some embodiments, the hardness of the material of the second isolation layer 214 is greater than that of the first isolation layer, and the material of the second isolation layer 214 is the same as the material of the stress adjustment layer 212. In addition, the thickness of the second isolation layer 214 is within a range of 10 nm to 20 nm, for example, 13 nm, 15 nm, or 18 nm. The thickness of the second isolation layer 214 is related to the material properties of the third isolation layer filled subsequently. The greater a coefficient of expansion of the third isolation layer, the higher the hardness of the second isolation layer 214, so as to ensure that the second isolation layer 214 has a good expansion suppression effect, thus preventing the expansion of the third isolation layer from damaging the structure of the second isolation layer 214.

The second isolation sublayer 213 is located between the stress adjustment layer 212 and the second isolation layer 214 to separate the stress adjustment layer 212 from the second isolation layer 214, and the stress adjustment layer 212 is sealed in the first isolation layer. Therefore, the stress adjustment layer 212 and the second isolation layer 214 are relatively independent. In other embodiments, since the first isolation layer exposes the stress adjustment layer, the stress adjustment layer and the second isolation layer can be formed in the same process step.

Specifically, a first isolation film covering the sidewall, corner, and bottom of the trench can be formed first, and then part of the first isolation film covering the corner of the trench can be etched to form a sub-trench to be filled with the stress adjustment layer. The sub-trench is located in the part of the first isolation film and formed as a blind hole, and the remaining first isolation film serves as the first isolation layer. Since the sub-trench is formed by etching the first isolation film, the first isolation layer exposes the sub-trench, and the second isolation layer covering the first isolation layer and the stress adjustment layer filling the sub-trench can be formed subsequently by the same deposition process.

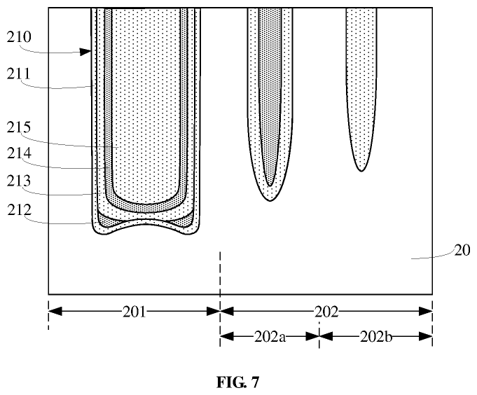

Referring to FIG. 7, a third isolation layer 215 is formed.

In some embodiments, after the formation of the second isolation layer 214, a spin coating process is used to form the third isolation layer 215 to fill up the trench 210. The spin coating process has good gap filling performance, which is beneficial to avoiding the case where the trench 210 is sealed in advance to cause holes in the third isolation layer 215. In this way, it is beneficial to ensuring that the third isolation layer 215 has good structural stability and that the third isolation layer 215 has good electrical isolation.

In some embodiments, the hardness of the material of the third isolation layer 215 is less than that of the second isolation layer 214. In this way, the second isolation layer 214 with a relatively high hardness can suppress the expansion of the third isolation layer 215 with a relatively low hardness, and prevent the expansion of the third isolation layer 215 from causing an excessive stress on the corner of the trench 210, thereby alleviating the problem of stress concentration at the corner of the trench 210, and improving the product yield.

In some embodiments, the material of the third isolation layer 215 is the same as the material of the first isolation layer, and the material of the first isolation layer and the material of the third isolation layer are both silicon dioxide with a relatively low dielectric constant and a low cost, which can both ensure the electrical isolation performance of the isolation structure and reduce the manufacturing cost.

In some embodiments, after the spin coating process, a high-temperature oxidation process is performed to cure the third isolation layer 215. During the high-temperature oxidation process, the third isolation layer 215 may expand due to heat. The second isolation layer 214 with a relatively high hardness can suppress the expansion of the third isolation layer 215, thereby preventing the expansion of the third isolation layer 215 from applying a further stress to the corner of the trench 210, alleviating the stress concentration problem at the corner of the trench 210, and improving the product yield.

In some embodiments, a stress adjustment layer with a relatively high hardness is arranged in the first isolation layer covering the corner of the trench to reduce the stress on the corners of the trench and avoid the stress concentration problem at the corner of the trench, thus improving the product yield.

Correspondingly, an embodiment of the present disclosure further provides a semiconductor structure, and the semiconductor structure can be manufactured using the above-mentioned manufacturing method of a semiconductor structure.

Referring to FIG. 7, the semiconductor structure includes: a substrate 20 having a trench 210 therein, the trench 210 including a corner located between a bottom and a sidewall, the corner protruding in a direction away from an opening of the trench 210 relative to the bottom; a first isolation layer, covering a surface of the sidewall, a surface of the corner and a surface of the bottom; a second isolation layer 214, covering a surface of the first isolation layer, a hardness of a material of the second isolation layer 214 being greater than that of the first isolation layer; and a stress adjustment layer 212, located in the first isolation layer between the corner and the second isolation layer 214, a hardness of a material of the stress adjustment layer 212 being greater than that of the first isolation layer.

In some embodiments, the first isolation layer includes a first isolation sublayer 211 and a second isolation sublayer 213. The first isolation sublayer 211 is located between the stress adjustment layer 212 and the substrate 20 to separate the stress adjustment layer 212 from the substrate 20. The second isolation sublayer 213 is located between the stress adjustment layer 212 and the second isolation layer 214 to separate the stress adjustment layer 212 from the second isolation layer 214.

In some embodiments, a surface of the stress adjustment layer 212 facing a middle part of the trench 210 is higher than or flush with a surface of a part of the first isolation sublayer 211 covering the bottom; the second isolation sublayer 213 comes into contact with the first isolation sublayer 211 on the surface of the bottom.

In some embodiments, a thickness of the first isolation sublayer 211 is within a range of 2 nm to 10 nm, such as 4 nm, 6 nm or 8 nm; the thickness of the second isolation sublayer 213 is within a range of 2 nm to 10 nm, such as 4 nm, 6 nm or 8 nm; a thickness of the second isolation layer 214 is within a range of 10 nm to 20 nm, for example, 13 nm, 15 nm, or 18 nm.

In some embodiments, a material of the stress adjustment layer 21 is the same as a material of the second isolation layer 214, the material of the first isolation layer includes silicon dioxide, and the material of the stress adjustment layer 212 includes silicon nitride.

In some embodiments, the semiconductor structure further includes a third isolation layer 215, the third isolation layer 215 fills up the trench 210, and a hardness of a material of the third isolation layer 215 is less than that of the second isolation layer 214.

In some embodiments, the substrate 20 includes a peripheral region 201 and an array region 202, and the stress adjustment layer 212 is located in the trench 210 in the peripheral region 201.

In some embodiments, a stress adjustment layer with a relatively high hardness is arranged in the first isolation layer covering the corner of the trench to reduce the stress on the corners of the trench and avoid the stress concentration problem at the corner of the trench, thus improving the product yield.

The ordinary skills in the art can understand that the implementations described above are particular embodiments for implementing the present disclosure. In practical uses, various changes in forms and details may be made to the implementations without departing from the spirit and scope of the present disclosure. Any person skilled in the art may make their own changes and modifications without departing from the spirit and scope of the present disclosure. Therefore, the protection scope of the present disclosure shall be subject to the protection scope of the claims.

What is claimed is:

1. A semiconductor structure, comprising:
a substrate having a trench therein, the trench comprising a corner between a bottom and a sidewall, the corner protruding in a direction away from an opening of the trench;
a first isolation layer, covering a surface of the sidewall, a surface of the corner and a surface of the bottom;
a second isolation layer, covering a surface of the first isolation layer, a hardness of a material of the second isolation layer being greater than that of the first isolation layer; and
a stress adjustment layer, located in the first isolation layer between the corner and the second isolation layer, a hardness of a material of the stress adjustment layer being greater than that of the first isolation layer.

2. The semiconductor structure according to claim 1, wherein the first isolation layer comprises a first isolation sublayer and a second isolation sublayer; the first isolation sublayer is located between the stress adjustment layer and the substrate to separate the stress adjustment layer from the substrate, and the second isolation sublayer is located between the stress adjustment layer and the second isolation layer to separate the stress adjustment layer from the second isolation layer.

3. The semiconductor structure according to claim 2, wherein a surface of the stress adjustment layer facing the opening of the trench is higher than or flush with a surface of a part of the first isolation sublayer covering the bottom.

4. The semiconductor structure according to claim 3, wherein the second isolation sublayer is in contact with the first isolation sublayer located on the surface of the bottom.

5. The semiconductor structure according to claim 2, wherein a thickness of the first isolation sublayer is within a range of 2 nm to 10 nm, and a thickness of the second isolation sublayer is within a range of 2 nm to 10 nm.

6. The semiconductor structure according to claim 1, wherein a thickness of the second isolation layer is within a range of 10 nm to 20 nm.

7. The semiconductor structure according to claim 1, wherein a material of the stress adjustment layer is the same as a material of the second isolation layer.

8. The semiconductor structure according to claim 1, wherein the material of the first isolation layer comprises silicon dioxide, and the material of the stress adjustment layer comprises silicon nitride.

9. The semiconductor structure according to claim 1, further comprising a third isolation layer, the third isolation layer filling up the trench, a hardness of a material of the third isolation layer being less than that of the second isolation layer.

10. The semiconductor structure according to claim 1, wherein the substrate comprises a peripheral region and an array region, and the stress adjustment layer is located in the trench in the peripheral region.

11. A manufacturing method of a semiconductor structure, comprising:
providing a substrate having trenches therein, the trench comprising corners between a bottom and sidewalls, the corner protruding in a direction away from an opening of the trench;
forming a first isolation layer and a stress adjustment layer, the first isolation layer covering a surface of the sidewall, a surface of the corner and a surface of the bottom, the stress adjustment layer being located in the first isolation layer covering the surface of the corner, a hardness of a material of the stress adjustment layer being greater than that of the first isolation layer; and
forming a second isolation layer, the second isolation layer covering a surface of the first isolation layer, a hardness of a material of the second isolation layer being greater than that of the first isolation layer.

12. The manufacturing method of a semiconductor structure according to claim 11, wherein the process step of forming the first isolation layer and the stress adjustment layer comprises:
forming a first isolation sublayer, the first isolation sublayer covering the surface of the sidewall, the surface of the corner and the surface of the bottom;
forming the stress adjustment layer, the stress adjustment layer covering a surface of the first isolation sublayer located on the surface of the corner; and
forming a second isolation sublayer, wherein the second isolation sublayer covering a surface of the stress adjustment layer and the surface of the first isolation sublayer, the first isolation sublayer and the second isolation sublayer constituting the first isolation layer.

13. The manufacturing method of a semiconductor structure according to claim 12, wherein the process step of forming the stress adjustment layer comprises:
forming a stress adjustment film, the stress adjustment film covering the surface of the first isolation sublayer; and
etching a part of the stress adjustment film by using a plasma etching process, the stress adjustment film on the surface of the first isolation sublayer on the surface of the corner being remained.

14. The manufacturing method of a semiconductor structure according to claim 11, wherein after the formation of the second isolation layer, a third isolation layer filling up the trench is formed, and a hardness of a material of the third isolation layer is less than that of the second isolation layer.

15. The manufacturing method of a semiconductor structure according to claim 14, wherein the third isolation layer is formed by using a spin coating process.

16. The manufacturing method of a semiconductor structure according to claim 14, wherein the material of the third isolation layer is the same as the material of the first isolation layer, and the material of the first isolation layer and the material of the third isolation layer are both silicon dioxide.

17. The manufacturing method of a semiconductor structure according to claim 15, wherein after the spin coating process, a high-temperature oxidation process is performed to cure the third isolation layer.
